(19) United States
(12) Patent Application Publication
(10) Pub. No.: US 2006/0022335 A1
(43) Pub. Date: Feb. 2, 2006

(54) CPU clamp

(76) Inventor: Li-Hui Kao, Taipei Shien (TW)

Correspondence Address: PRO-TECHTOR INTERNATIONAL, 20775 Norada Court, Saratoga, CA, 95070-3018, US

(21) Appl. No.: 10/903,787

(22) Filed: Jul. 29, 2004

(51) Int. Cl. H05K 7/12

(52) U.S. Cl. 257/727; 361/783

(57) ABSTRACT

The present invention is a CPU clamp that a CPU can be taken out of a handling cell and placed on a mount without using a hand, which prevents damage to the CPU, due to being carelessly dropped.

### BACKGROUND OF THE INVENTION

(a) Field of the Invention

The present invention relates to a CPU clamp that clamps a CPU to load on a desired mount.

(b) Description of the Prior Art

Referring to FIG. 1. A CPU 100 is loaded on a handling cell 300 before final application. Referring to FIG. 2. A CPU 100 is placed on a mount 200 having a base plate 201 and connection pins 202, wherein the circuit on the bottom of the CPU 100 connects connection pins 202. To relocate the CPU 100, a conventional way is to use a bare hand to take the CPU 100 out of the handling cell 300 and then place it on the mount 200, which may affect the CPU 100 functioning due to hand sweat or static electricity, besides a risk that the CPU 100 can be dropped, out of a careless operation, that may damage connection pins.

### SUMMARY OF THE INVENTION

The present invention is related to a CPU clamp that a CPU can be clamped and placed on a mount without using a hand, thereby preventing being dropped out of a careless operation, which may damage the CPU.

To enable a further understanding of the said objectives and the technological methods of the invention herein, the brief description of the drawings below is followed by the detailed description of the preferred embodiments.

### BRIEF DESCRIPTION OF THE DRAWING

FIG. 1 shows a perspective view of a CPU on a handling cell.

FIG. 2 shows an exploded elevational view of a CPU on a mount.

FIG. 3 shows a perspective view of the present invention.

FIG. 4 shows an upside-down perspective view of the present invention.

FIG. 5 shows an exploded elevational view of a CPU before being clamped by the present invention.

FIG. 6 shows an exploded elevational view of a CPU being clamped by the present invention.

FIG. 7 shows an exploded elevational view of a CPU being clamped by the present invention before loading on a mount.

FIG. 8 shows a perspective view of a CPU being clamped and loaded on a mount by using the present invention.

FIG. 9 shows a CPU loaded on the mount after removing the present invention.

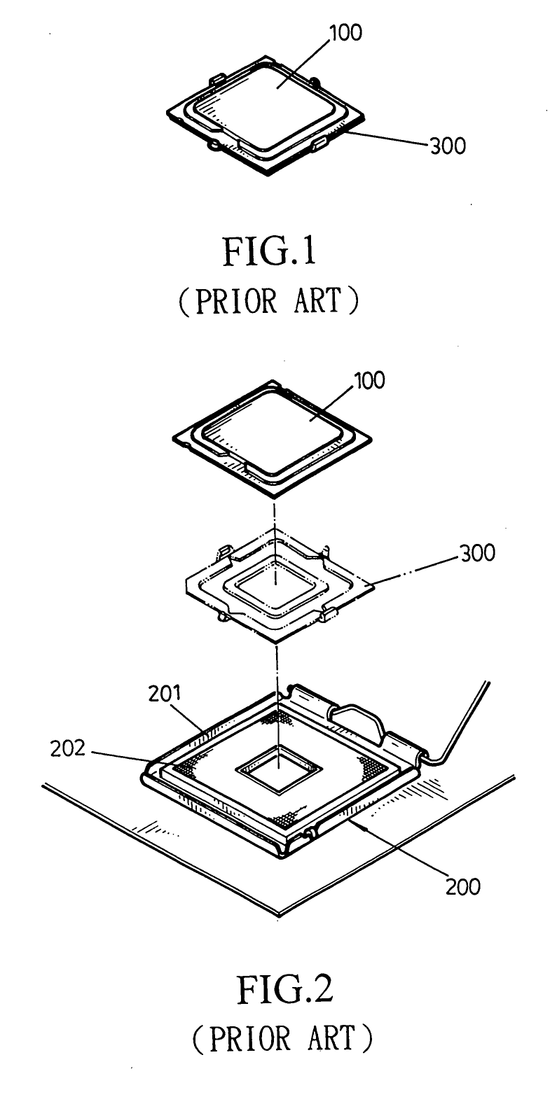

### DETAILED DESCRIPTION OF THE PREFERRED EMBODIMENTS

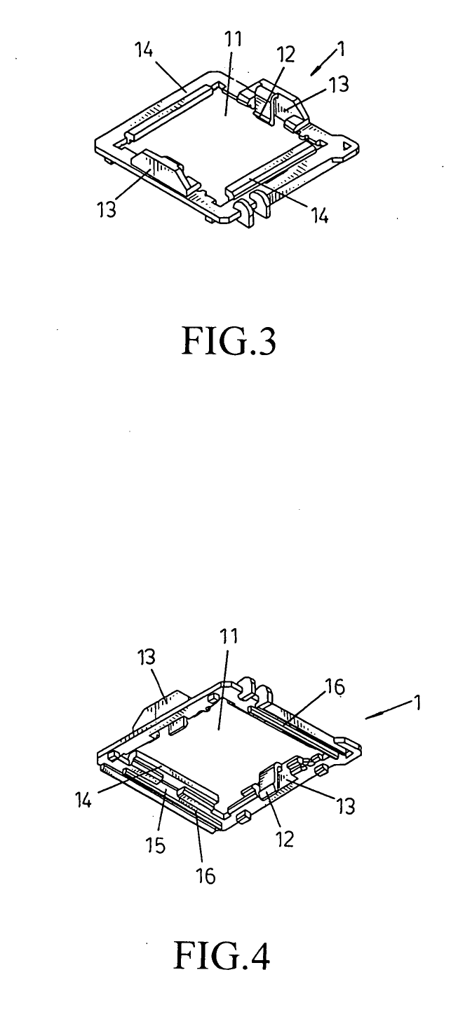

Referring to FIGS. 3 and 4. The present invention is a CPU clamp 1 having a hollow 11, an elastic hook 12 formed on a back plate 13 on each opposite side, and a long locking block 14 formed on each side adjoining thereof, wherein each locking lock 14 having a reverse “L” cross section and including a gap 15 formed on a bottom, and a positioning strip 16 formed outside.

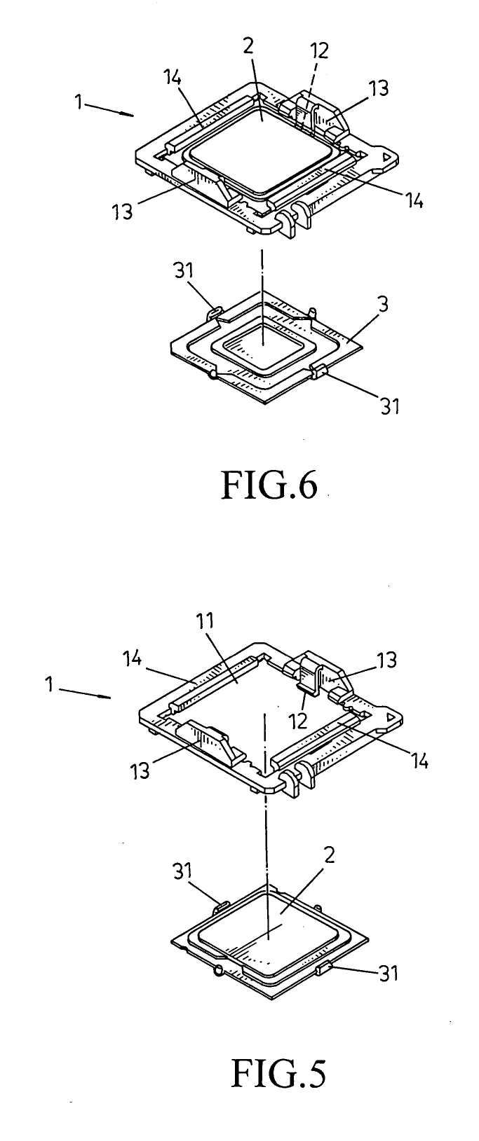

Referring to FIG. 5. A CPU 2 is loaded on a handling cell 3, with a side clamp 31 clamping each opposite side. Referring to FIG. 6. To take the CPU 2 out of the handling cell 3, capping the hollow 11 of the CPU clamp 1 on the CPU 2, with each gap 15 corresponding to each side clamp 31, to enable each locking block 14 above each gap 15 to press down each side clamp 31, thereby detaching the CPU 2 from the handling cell 3 to facilitate taking out the CPU 2.

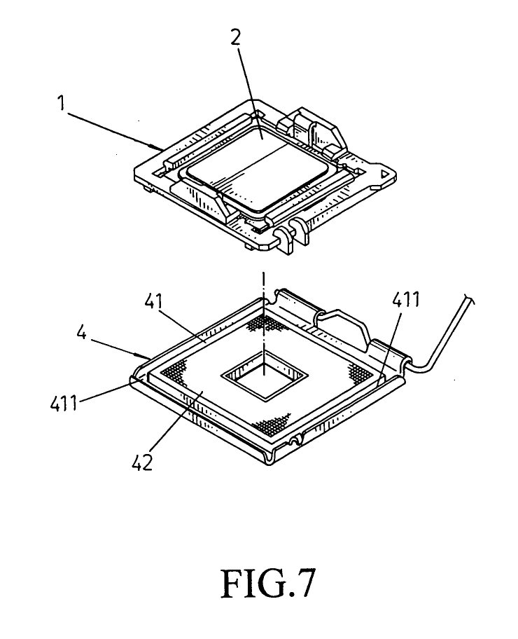

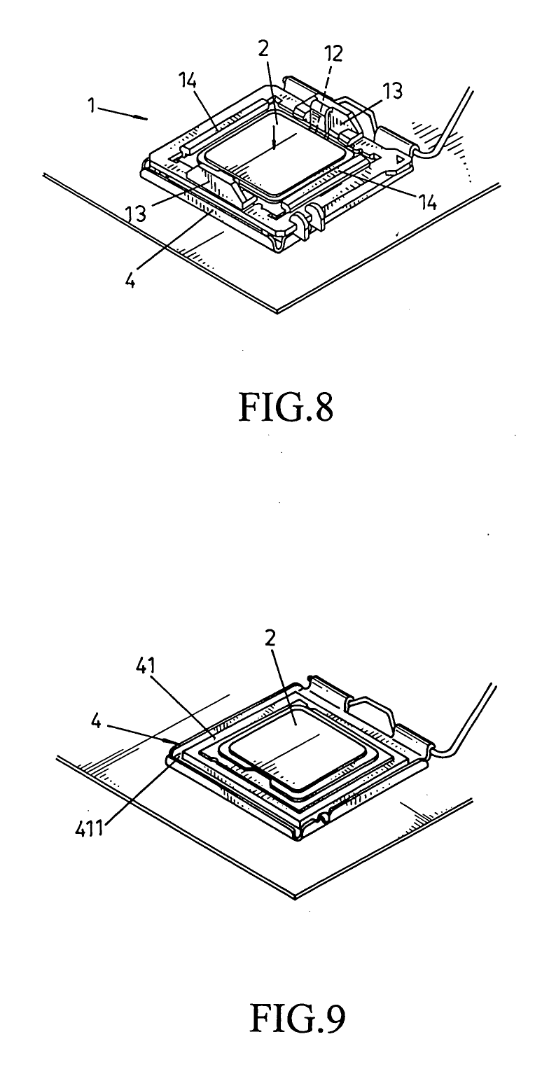

Referring to FIG. 7. To install the CPU 2 on a base plate 41 of a mount 4, capping the CPU clamp 1 on the mount 4, with each positioning strip 16 being embedded in a groove 411 formed between the mount 4 and the base plate 41. Referring to FIG. 8. By pressing the CPU 2, each elastic hook 12 will be forced moving outwards, thereby detaching from the CPU 2. Referring to FIG. 9. By removing the CPU clamp 1, the CPU 2 is then loaded on the base plate 41, thereby enabling the circuit on the bottom of the CPU 2 connecting with connection pins 42.

In summary, the present invention is a CPU clamp which loads the CPU 2 on a mount 4 without using a hand, thereby preventing damage to the CPU 2, due to being carelessly dropped.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. A CPU clamp comprising a hollow, an elastic hook formed on a back plate on each opposite side, and a locking block formed on each side adjoining thereof, wherein each locking block having a gap formed on a bottom and a positioning strip formed outside;
by capping the CPU clamp on a CPU, with each gap corresponding to each side clamp, to enable each locking block above each gap to press down each side clamp, thereby detaching the CPU from a handling cell;
by capping the CPU, being framed by the CPU clamp, on a base plate of a mount, with each locking block being embedded into a groove formed between the mount and the base plate, and by pressing the CPU to detach each elastic hook of the CPU clamp from the CPU, due to an outward movement of each elastic hook, the CPU 2 thereby being loaded on the mount.

2. The CPU clamp as recited in claim 1, wherein the locking block comprising a reverse “L” cross section.
